(19) United States
(12) Patent Application Publication
(10) Pub. No.: US 2025/0107194 A1
(43) Pub. Date: Mar. 27, 2025

(54) SILICON CARBIDE POWER MOSFET AND METHOD FOR MANUFACTURING SAME

(71) Applicant: Microchip Technology Incorporated, Chandler, AZ (US)

(72) Inventors: Shesh Mani Pandey, Gilbert, AZ (US); Bruce Odekirk, Portland, OR (US); Sami El Hageali, Castle Rock, CO (US)

(73) Assignee: Microchip Technology Incorporated, Chandler, AZ (US)

(21) Appl. No.: 18/891,853

(22) Filed: Sep. 20, 2024

Related U.S. Application Data
(63) Continuation of application No. 63/539,754, filed on Sep. 21, 2023.

(51) Int. Cl. H01L 29/16; H01L 21/02

(52) U.S. Cl. CPC H10D 62/8325; H01L 21/02236; H01L 21/02271; H01L 21/02378; H01L 21/02529

(57) ABSTRACT

A method of manufacturing a semiconductor device is provided. The method may include implanting a silicon-rich layer on a surface of a silicon carbide substrate, and growing a gate oxide layer on the silicon-rich layer on the surface of the silicon carbide substrate.

### CROSS-REFERENCE TO RELATED APPLICATION

The present application claims priority to U.S. Provisional Patent Application No. 63/539,754, entitled: Silicon Carbide Power MOSFET and Method for Manufacturing Same, filed on Sep. 21, 2023, the contents of which are hereby incorporated by reference in their entirety.

### TECHNICAL FIELD

The present disclosure relates generally to methods for manufacturing semiconductor devices, and more specifically to manufacturing semiconductor devices with silicon carbide substrates and a gate oxide interface with the silicon carbide substrate.

### SUMMARY

According to an aspect of one or more examples, there is provided a method of manufacturing a semiconductor device. The method may include implanting a silicon-rich layer on a surface of a silicon carbide substrate, and growing a gate oxide layer on the silicon-rich layer. The silicon-rich layer may have a carbon to silicon ratio equal to or less than approximately 0.98. The silicon-rich layer may have a silicon concentration approximately between 1e¹⁹ and 5e²² atoms per cubic centimeter. Forming the gate oxide layer may include oxidizing silicon from the silicon-rich layer to form a gate oxide layer of silicon dioxide. The gate oxide layer of silicon dioxide may be formed or grown by a thermal oxidation process of the silicon-rich layer. The gate oxide layer of silicon dioxide may be formed or grown by a chemical vapor deposition (CVD) process of the silicon-rich layer. The silicon-rich layer may have a thickness that is approximately half a thickness of the gate oxide layer. The silicon-rich layer may have a thickness that is approximately equal to a thickness of the gate oxide layer.

According to another aspect of one or more examples, there is provided a semiconductor device that may include a silicon carbide substrate, a silicon-rich layer formed on a surface of the silicon carbide substrate, and a gate oxide layer formed on the silicon-rich layer. The silicon-rich layer may have a carbon to silicon ratio equal to or less than approximately 0.98. The silicon-rich layer may have a silicon concentration approximately between 1e¹⁹ and 5e²² atoms per cubic centimeter. The silicon-rich layer may have a thickness that is approximately half the thickness of the gate oxide layer. The silicon-rich layer may have a thickness that is approximately equal to a thickness of the gate oxide layer.

### BRIEF DESCRIPTION OF DRAWINGS

FIG. 1 shows a method of manufacturing a semiconductor device according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

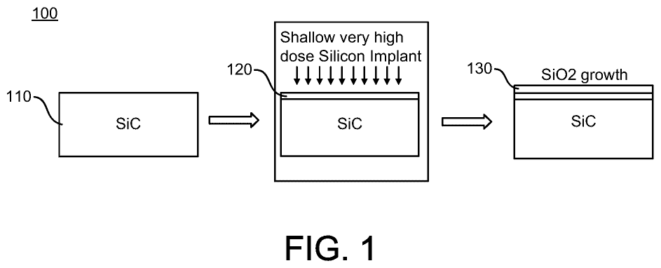

FIG. 1 shows a method 100 of manufacturing a semiconductor device according to one or more examples. Silicon carbide (SiC) is often used as a substrate to create many semiconductor devices, and may result in reduced switching losses, higher power density, improved heat dissipation, and increase bandwidth as compared with other materials. Some semiconductor devices, such as metal-oxide-semiconductor field-effect transistors (MOSFETs) include a gate oxide layer that is a dielectric layer that separates the silicon carbide substrate from a gate electrode, which may be made of metal or other conductive material.

When forming the gate oxide layer on a silicon carbide substrate, the interface between the silicon carbide substrate and the gate oxide layer (for example, a gate oxide layer made of silicon dioxide) may be very rough. The rough interface between the gate oxide layer and the silicon carbide substrate may degrade carrier mobility in the silicon carbide substrate, which may limit device performance. Referring to FIG. 1, a silicon carbide substrate 110 is used as a base substrate. A silicon-rich layer 120 may be grown on a surface of the silicon carbide substrate 110 or implanted within an upper portion of the silicon carbide substrate 110. According to one or more examples, the silicon-rich layer 120 may be approximately 100 Å to 500 Å thick, though other thicknesses may be used depending on the application. For example, the amount of silicon used to create the silicon-rich layer 120 may depend on the thickness of the gate oxide layer 130 to be formed on the silicon-rich layer 120. According to one or more example embodiments, the thickness of the silicon-rich layer 120 may be approximately half the thickness of the gate oxide layer 130. According to one or more examples, the thickness of the silicon-rich layer 120 may be approximately equal to the thickness of the gate oxide layer 130. The silicon-rich layer 120 may be a high dose layer. For example, the silicon-rich layer 120 may have a silicon concentration approximately between 1e¹⁹ and 5e²² atoms per cubic centimeter. According to one or more example embodiments, the silicon-rich layer 120 may have a very low carbon to silicon ratio. For example, the carbon-silicon ratio may be equal to or less than approximately 0.98.

As shown in FIG. 1, a gate oxide layer 130 may be formed on the silicon-rich layer 120. For example, the gate oxide layer 130 may be a layer of silicon dioxide (SiO₂), which may be formed or grown by a thermal oxidation process of the silicon-rich layer 120. In various examples, the gate oxide layer 130 may be a layer of SiO₂, which may be formed or grown by a chemical vapor deposition (CVD) process of the silicon-rich layer 120. By forming the gate oxide layer 130 on a silicon-rich layer 120 having a higher concentration of silicon than, for example, the silicon carbide substrate 110, the interface between the gate oxide layer 130 and the silicon-rich layer 120 may be smoother, which may improve carrier mobility.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A method of manufacturing a semiconductor device, the method comprising:
implanting a silicon-rich layer on a surface of a silicon carbide substrate; and
growing a gate oxide layer on the silicon-rich layer on the surface of the silicon carbide substrate.

2. The method of claim 1, wherein the silicon-rich layer has a carbon to silicon ratio equal to or less than approximately 0.98.

3. The method of claim 1, wherein the silicon-rich layer has a silicon concentration approximately between 1e¹⁹ and 5e²² atoms per cubic centimeter.

4. The method of claim 1, wherein the forming of the gate oxide layer includes oxidizing silicon from the silicon-rich layer to form a gate oxide layer of silicon dioxide.

5. The method of claim 1, wherein the silicon-rich layer has a thickness that is approximately half a thickness of the gate oxide layer.

6. The method of claim 4, wherein the gate oxide layer of silicone dioxide is formed or grown by a thermal oxidation process of the silicon-rich layer.

7. The method of claim 4, wherein the gate oxide layer of silicone dioxide is formed or grown by a chemical vapor deposition (CVD) process of the silicon-rich layer.

8. The method of claim 1, wherein the silicon-rich layer has a thickness that is approximately equal to a thickness of the gate oxide layer.

9. A semiconductor device comprising:
a silicon carbide substrate;
a silicon-rich layer formed on a surface of the silicon carbide substrate; and
a gate oxide layer formed on the silicon-rich layer.

10. The semiconductor device of claim 9, wherein the silicon-rich layer has carbon to silicon ratio equal to or less than approximately 0.98.

11. The semiconductor device of claim 9, wherein the silicon-rich layer has a silicon concentration approximately between 1e¹⁹ and 5e²² atoms per cubic centimeter.

12. The semiconductor device of claim 9, wherein the silicon-rich layer has a thickness that is approximately half a thickness of the gate oxide layer.

13. The semiconductor device of claim 9, wherein the silicon-rich layer has a thickness that is approximately equal to a thickness of the gate oxide layer.
